(19) United States
(12) Patent Application Publication
(10) Pub. No.: US 2015/0022200 A1
(43) Pub. Date: Jan. 22, 2015

(54) OPTICALLY PUMPED MAGNETOMETER AND OPTICAL PUMPING MAGNETIC FORCE MEASURING METHOD

(71) Applicant: CANON KABUSHIKI KAISHA, Tokyo (JP)

(72) Inventors: Sunao Ichihara, Kawasaki-shi (JP); Tetsuo Kobayashi, Kyoto-shi (JP)

(21) Appl. No.: 14/331,552

(22) Filed: Jul. 15, 2014

(30) Foreign Application Priority Data
Jul. 18, 2013 (JP) 2013-149135

(51) Int. Cl. G01R 33/26

(52) U.S. Cl. CPC G01R 33/26
USPC 324/304

(57) ABSTRACT

An optically pumped magnetometer having a single optical axis using atomic electron spin or nuclear spin includes a detection unit configured to detect an angle of a polarization plane of probe light having components of linear polarization and a modulation unit configured to apply a modulation to the angle of the polarization plane of the probe light having the components of linear polarization. The modulation unit is configured to control an offset in applying the modulation to the angle of the polarization plane of the probe light having the components of linear polarization according to the angle of the polarization plane of the probe light detected by the detection unit.

### BACKGROUND

1. Technical Field

The present disclosure relates to an optically pumped magnetometer and an optical pumping magnetic force measuring method, and specifically, to an optically pumped magnetometer using atomic electron spin or nuclear spin.

2. Description of the Related Art

There has been known an optically pumped magnetometer using atomic electron spin or nuclear spin.

Cort Johnson, Peter D. D. Schwindt, and Michael Weisend, Appl. Phys. Lett. 97, 243703 (2010) (hereinafter referred to as Non-patent Literature 1) discloses an optically pumped magnetometer which includes a cell containing alkali metal gas, a pump light source, and a probe light source so as to detect a weak magnetic field.

When an object magnetic field to be measured is applied to spin of an atom group, the spin of the atom group is polarized by the pump light rotates. This optically pumped magnetometer measures the above rotation as a rotation of a polarization plane of probe light.

Further, a method is disclosed for measuring the magnetic field by making the pump light and the probe light enter the cell from the same direction in order to miniaturize and simplify a sensor.

Also, S. J. Seltzer “Developments in Alkali-Metal Atomic Magnetometry”, Dissertation, Princeton University (2008) (hereinafter referred to as Non-patent Literature 2) discloses a method for detecting the rotation of the polarization plane by a difference detection and a method for applying a sinusoidal modulation to the angle of the polarization plane of the probe light by using a phase modulation element.

In Non-patent Literature 1 above, an optical magnetometer having a single optical axis in which pump light and probe light are incident through the same optical path is configured.

In such optical magnetometers having a single optical axis, there has been a problem that noise which could have been canceled by a difference detection cannot be canceled since the polarization plane of the probe light rotates when a size of a spin polarization fluctuates by an intensity fluctuation of the pump light.

Also, the method in Non-patent Literature 2 includes applying the sinusoidal modulation to the angle of the polarization plane and shifting a measuring signal to a high-frequency area so as to reduce an influence of noise other than environmental magnetic field noise. In the former noise, noise power is characterized by a reciprocal of a frequency.

However, even if such a method is simply combined with the optical magnetometer having a single optical axis, the influence by the fluctuation of the size of the spin polarization cannot be removed.

### SUMMARY

The present disclosure has been made in consideration of the above problems. The present disclosure provides an optically pumped magnetometer and an optical pumping magnetic force measuring method capable of suppressing the influence by the fluctuation of the spin polarization and reducing the noise.

An optically pumped magnetometer having a single optical axis using atomic electron spin or nuclear spin according to an embodiment includes a detection unit configured to detect an angle of a polarization plane of a probe light having components of linear polarization.

The optically pumped magnetometer further includes a modulation unit configured to apply a modulation to the angle of the polarization plane of the probe light having the components of linear polarization.

The modulation unit is configured to control an offset in applying the modulation to the angle of the polarization plane of the probe light having the components of linear polarization according to the angle of the polarization plane of the probe light detected by the detection unit.

A single-optical-axial optical pumping magnetic force measuring method according to an embodiment includes detecting an angle of a polarization plane of probe light having components of linear polarization by using atomic electron spin or nuclear spin.

The optical pumping magnetic force measuring method further includes controlling an offset in applying a modulation to the angle of the polarization plane of the probe light having the components of linear polarization according to the detected angle of the polarization plane of the probe light.

Further features of the present invention will become apparent from the following description of exemplary embodiments (with reference to the attached drawings).

### BRIEF DESCRIPTION OF THE DRAWINGS

FIG. 1 is a schematic diagram of an exemplary configuration of an optically pumped magnetometer in an embodiment of the present invention.

FIG. 2 is a schematic diagram of an exemplary configuration of an optically pumped magnetometer in a first embodiment of the present invention.

FIG. 3 is a schematic diagram of an exemplary configuration of an optically pumped magnetometer in a second embodiment of the present invention.

FIG. 4 is a schematic diagram of an exemplary configuration of an optically pumped magnetometer in a third embodiment of the present invention.

### DESCRIPTION OF THE EMBODIMENTS

An exemplary configuration of an optically pumped magnetometer having a single optical axis using atomic electron spin or nuclear spin and an optical pumping magnetic force measuring method in an embodiment of the present invention will be described.

The optically pumped magnetometer includes a modulation unit which adds an offset to an angle of a polarization plane of probe light having components of linear polarization and applies a modulation to the angle of the polarization plane.

By the modulation unit, for example, a sinusoidal modulation is applied, and a difference between the rotations of the polarization plane is detected. A measured magnetic signal is read from a harmonic component of a modulation frequency, and at the same time, a signal of a frequency equal to or lower than a measuring frequency is read as a control signal. The control signal is input into a modulator of the polarization plane. The optically pumped magnetometer is configured such that the offset caused by the fluctuation of the polarization plane of the probe light can be controlled to be constantly removed in a low-frequency area having a frequency equal to or lower than the measuring frequency. This enables removing an influence by a fluctuation of a spin polarization and reducing noise.

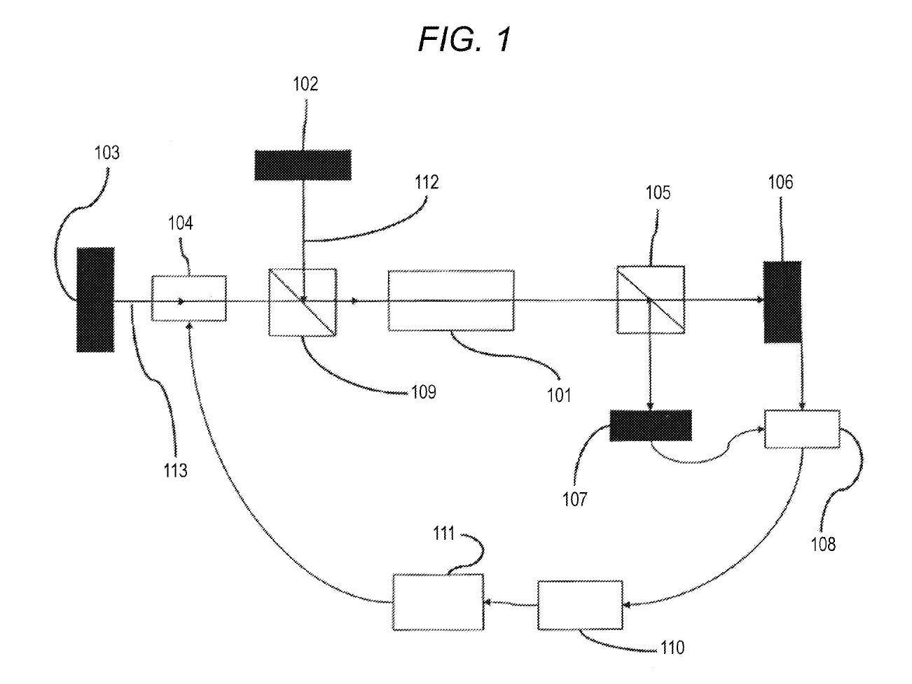

Specifically, as shown in FIG. 1, the optically pumped magnetometer includes a cell 101 containing an alkali metal atom group (atom cluster) such as potassium (K), a pump light source 102, and a probe light source 103.

Further, the optically pumped magnetometer includes a polarization plane angle modulation system 104, a polarization beam splitter element 105, photodetectors 106 and 107, a difference circuit 108, a beam overlapping unit 109, a frequency separation unit 110, and a polarization plane angle modulation system control unit 111.

The pump light source 102 emits pump light 112, and polarized light of the pump light 112 is circularly polarized light.

The probe light source 103 emits probe light 113, and polarized light of the probe light 113 is linearly polarized light.

The pump light 112 is overlapped with the same optical path as the probe light 113 by the beam overlapping unit 109.

At this time, the above optical paths may not be exactly the same. The pump light only has to sufficiently pass through a space in the cell through which the probe light passes.

Spin directions of the potassium atoms in the cell 101 are arranged in the same direction by optical pumping of the pump light 112, and the potassium atoms are spin-polarized. At this time, a wavelength of the pump light 112 is set to be identical to a D1 transition wavelength of the potassium atoms.

The spin of the spin-polarized atoms performs precession by receiving a torque suitable for a measured magnetic field.

The light which has been emitted from the probe light source 103 passes through the polarization plane angle modulation system 104. Modulation is applied to an angle of a polarization plane of the probe light. The polarization plane of the probe light 113, which has passed through the cell 101, causes a paramagnetic Faraday rotation according to the precession of the spin.

The probe light 113 enters the polarization beam splitter element 105 and is divided into reflection and transmission at an intensity according to the angle of the polarization plane.

The photodetector 106 detects the light having passed through the polarization beam splitter element 105, and the photodetector 107 detects the light reflected by the polarization beam splitter element 105. The difference circuit 108 measures the difference between components divided by the polarization beam splitter element 105. An output signal from the difference circuit 108 is input into the frequency separation unit 110 and is separated into a magnetic field response signal and a signal for controlling the polarization plane angle modulation system.

The control signal is input into the control circuit (control unit) 111, and the offset of the polarization plane angle modulation system 104 is controlled so as to constantly maintain a balance between the intensities of the light beams, which enter the photodetectors 106 and 107, in a low frequency band equal to or lower than a measuring frequency.

In a case where the polarization beam splitter element 105 is an ideal polarization beam splitter element, all the incident light beams may pass through the element at a certain angle of the polarization plane. It is assumed that the angle is θ₀=0°.

All polarized light beams having an angle of 90° relative to the angle above may be reflected by the polarization beam splitter element 105. Also, incident polarized light having a polarization plane angle of 45° or −45° is divided into the transmission and the reflection. The transmitted light has an equal light intensity to the reflected light.

Because outputs of the photodetectors 106 and 107 are equal to each other, an output of the difference circuit 108 becomes 0.

Therefore, when an angle of the initial polarization plane is adjusted to have an angle of θ₀=45° or θ₀=−45° in a case where a measuring magnetic field does not exist, noise such as light intensity noise has a similar influence on the outputs of both the photodetector 106 on the transmission side and the photodetector 107 on the reflection side. The noise such as the light intensity noise cancels each other out in the output of the difference circuit. Therefore, the noise can be reduced.

First, a case is considered where a bias magnetic field and the measuring magnetic field do not exist, and the spin polarization by the pump light exists. At this time, the output V (t) of the difference circuit is expressed by the following formula 1.

V(t)=V₀ cos(2θₚ)

V(t)=V₀ cos(2θₚ) (formula 1)

Here, V₀ represents a conversion coefficient, which includes a probe light intensity, an absorption coefficient and the like, from a polarization angle to the output of the difference circuit. θₚ represents a rotation amount of the polarization plane of the probe light which causes the Faraday rotation by the spin polarized by the pump light.

Since the rotation amount θₚ is proportionate to a magnitude of the spin polarization, the rotation amount θₚ changes according to the pump light intensity. Next, a case is considered where a measured oscillating field is applied to this situation. When the measured oscillating field is applied to an axis perpendicular to the pump light, the spin oscillates according to the magnetic field.

V(t)=V₀ cos(2θₚ+2β(B_{measured})sin(ωₛt+φₛ)) (formula 2)

β (B_{measured}) represents an amplitude of rotation of the polarization plane to the spin of the atoms which has rotated in the measured magnetic field. ωₛ represents an angular frequency of the measured oscillating field. φₛ represents a phase of a signal. At this time, a static magnetic field is applied as the bias magnetic field in a direction of the measured oscillating field. This allows an action on the spins of the respective atoms to constantly perform Larmor rotation. Therefore, the spin of the atom group rotates at an angle in which a balance between an action by the pump light to polarize and an action by the bias magnetic field to perform Larmor rotation is maintained.

As a result, the spin of the atom group has bigger β (B_{measured}) than the spin of the atom group in a measured oscillating field having the same intensity, because components which are perpendicular to the pump light increase.

However, when a large magnetic field is applied, relaxation of the spin becomes larger, and the amplitude β (B_{measured}) inversely becomes smaller.

Further, a case is considered where the polarization plane angle modulation system 104 applies the modulation to the angle of the polarization plane at θ_{offset} as an offset and at a frequency ω_{mod}, and an oscillating field which oscillates at an angular frequency ωₛ is measured as the measured magnetic field.

At this time, the output V (t) of the difference circuit is expressed by the following formula 3.

V(t)=V₀ cos(2θ+2β sin(ωₛt+φₛ)+2f(θ_{offset},α_{mod},ω_{mod},φ_{mod},t)) (formula 3)

Here, f (θ_{offset}, α_{offset}, φ_{offset}, t) represents a function of the modulation which is applied to the angle of the polarization plane of the probe light 113. θ_{offset} represents an offset of the modulation function, α_{mod} represents an amplitude of the modulation, ω_{mod} represents a modulation frequency, and φ_{mod} represents a phase of the modulation frequency.

A case where a sinusoidal wave is used as a modulation signal is considered. In this case, formula 3 is expressed as formula 4.

f(θ_{offset},α_{mod},ω_{mod},φ_{mod},t)=α_{mod} sin(ω_{mod}t+φ_{mod})θ_{offset} (formula 4)

When a minute measuring magnetic field is measured, it is assumed to be β<<1, and formula 3 is deformed as formula 5.

$$\begin{matrix}V ( t ) = & {V}_{0} cos ( 2 {θ}_{p} + 2 {θ}_{offset} + 2 β sin ( {ω}_{s} t + {φ}_{s} ) + \\ & 2 {α}_{mod} sin ( {ω}_{mod} t + {φ}_{mod} ) ) \\ \approx & {V}_{offset} + {V}_{cos , 0} + {V}_{cos , 1} + {V}_{sin , 0} + {V}_{sin , 1}\end{matrix} \qquad ( formula 5 )$$

Here, V_{offset}, V_{cos,0}, V_{cos,1}, V_{sin,0}, and V_{sin,1} are expressed by formula 6.

$$\begin{matrix}{V}_{offset} = {V}_{0} {J}_{0} ( 2 β ) {J}_{0} ( 2 {α}_{mod} ) cos ( 2 {θ}_{p} + 2 {θ}_{offset} ) \\ {V}_{cos , 0} = 2 {V}_{0} {J}_{0} ( 2 β ) cos ( 2 {θ}_{p} + \\ 2 {θ}_{offset} ) {\sum }_{k = 1}^{∞} {J}_{2 k} ( 2 {α}_{mod} ) cos ( 2 k ( {ω}_{mod} t + {φ}_{mod} ) ) \\ {V}_{cos , 1} = 2 {V}_{0} {J}_{1} ( 2 β ) cos ( 2 {θ}_{p} + 2 {θ}_{offset} ) \times \\ {\sum }_{k = 1}^{∞} {J}_{2 k - 1} ( 2 {α}_{mod} ) ( cos ( ( {ω}_{s} + 2 k - 1 ) {ω}_{mod} ) t + \\ {φ}_{s} + ( 2 k - 1 ) {φ}_{mod} ) - cos ( ( ( 2 k - 1 ) {ω}_{mod} - \\ {ω}_{s} ) t + ( 2 k - 1 ) {φ}_{mod} - {φ}_{s} ) )\end{matrix} \qquad ( formula 6 )$$

J₀, J₁, and J₂ respectively represent zero order, first order, and second order Bessel functions. V_{offset} is an offset component of the output. V_{cos,0} and V_{sin,0} represent oscillations of the angle of the polarization plane by the modulation. V_{cos,1} and V_{sin,1} represent responses to the measured magnetic field. When the offset of the modulation function θ_{offset} is controlled so as to be θₚ+θ_{offset}=±45°, V_{offset} V_{cos,0}, and V_{cos,1} become 0, and V_{sin,1} is maximized. This indicates that the light is divided by the polarization plane angle modulation system 104 and that a difference of a component other than a signal component is obtained by the difference between the outputs of the photodetectors 106 and 107. The component other than the signal component is canceled out.

The response to the measured magnetic field V_{sin,1} is used as the response to the measured magnetic field, and the offset component of the output V_{offset} is obtained as the control signal by the frequency separation unit 110, and the offset of the modulation function θ_{offset} is controlled so that the offset component of the output V_{offset} becomes 0. Then, the balance between the intensities of light beams, which enter the photodetectors 106 and 107, can be constantly maintained in a low frequency band lower than the measuring frequency with the response to the magnetic signal maximizing.

A low-pass filter or the like can be used as the frequency separation unit 110.

The response to the magnetic signal of a component of k=1, which is a harmonic component of the modulation frequency, out of the response to the measured magnetic field V_{sin,1} is the largest. Therefore, it is preferable to apply demodulation by the harmonic of the modulation frequency.

Next, as an example of a noise reduction effect, an effect of the probe light on the light intensity noise is considered. Now, a case is considered where the probe light has the light intensity noise, and the pump light intensity changes, whereby the polarization plane rotates at an angle corresponding to a constant number.

At this time, in formula 5, it may be expressed as V₀→V (t) in consideration of a time dependence. It is assumed that the Fourier transforms of V_{offset}, V_{cos,0} and V_{sin,0} are V_{offset} (ω), V_{cos,0}(ω), and V_{sin,0} (ω). It is also assumed that a noise power spectral density is β<<1. Then, the following formula 7 is obtained.

$$\begin{matrix}{Φ}_{offset} ( ω ) ∼ \vert {V}_{offset} ( ω ) {\vert}^{2} = \vert {V}_{0} ( ω ) {J}_{0} ( 2 β ) {J}_{0} ( 2 {α}_{mod} ) cos ( \frac{π}{2} + 2 {Δθ}_{p} ) {\vert}^{2} \\ {Φ}_{cos , 0} ( ω ) ∼ \vert {V}_{cos , 0} ( ω ) {\vert}^{2} = \vert {J}_{0} ( 2 β ) cos ( \frac{π}{2} + 2 {Δθ}_{p} ) {\sum }_{k = 1}^{∞} {J}_{2 k} ( 2 {α}_{mod} ) ( {V}_{0} ( 2 k {ω}_{mod} + ω ) + {V}_{0} ( 2 k {ω}_{mod} - ω ) ) {\vert}^{2} \\ {Φ}_{sin , 0} ( ω ) ∼ \vert {V}_{sin , 0} ( ω ) {\vert}^{2} = \vert {J}_{0} ( 2 β ) sin ( \frac{π}{2} + 2 {Δθ}_{p} ) {\sum }_{k = 1}^{∞} {J}_{2 k - 1} ( 2 {α}_{mod} ) ( {V}_{0} ( ( 2 k - 1 ) {ω}_{mod} + ω ) - {V}_{0} ( ( 2 k - 1 ) {ω}_{mod} - ω ) ) {\vert}^{2}\end{matrix} \qquad ( formula 7 )$$

Here, Δθₚ represents a change amount of the rotation of the polarization plane caused by the change of the pump light intensity. When it is assumed that a power spectral component of noise which is characterized by a reciprocal of the frequency is Φ_{sys} (ω), the minimum βₘᵢₙ of β is expressed as follows based on some calculations.

$${β}_{min} \approx \frac{\sqrt{\begin{matrix}{Φ}_{offset} ( {ω}_{s} ) + {Φ}_{cos , 0} ( {ω}_{s} ) + \\ {Φ}_{sin , 0} ( {ω}_{s} ) + {Φ}_{sys} ( {ω}_{mod} + {ω}_{s} )\end{matrix}}}{{J}_{2} ( 2 {α}_{mod} ) {V}_{0} ( 0 )} \qquad ( formula 8 )$$

Here, V₀ (0) represents an average intensity of the probe light. Next, a case is considered where the control is operated so as to be Δθₚ→0. At this time, it is expressed by V_{offset} (ω)→0 and V_{cos,0} (ω)→0. The minimum βₘᵢₙ of β is expressed as follows.

$${β}_{min} \approx \frac{\sqrt{{Φ}_{sin , c} ( {ω}_{s} ) + {Φ}_{sys} ( {ω}_{mod} + {ω}_{s} )}}{{J}_{2} ( 2 {α}_{mod} ) {V}_{0} ( 0 )} \qquad ( formula 9 )$$

This indicates that the noise caused by the light intensity is reduced, because DC components are operated at a balanced position to cancel each other out by adjusting the offset of the polarization plane to be balanced in the difference detection.

Also, a method for controlling the rotation amount θₚ to become θₚ+θ_{offset}=±45° can be used. Since the rotation amount θₚ depends on the intensity and frequency of the pump light, by controlling the intensity and frequency of the pump light, V_{offset}, V_{cos,0}, and V_{cos,1} can be 0, and V_{sin,1} can be maximized.

Also, a square wave signal can be used as the modulation signal. A case is considered where the square wave, in which the polarization plane alternately has angles of 45° and −45°, is used as the modulation signal. That is, at these angles of the polarization plane, in each polarization state, the intensities of the transmitted light and reflected light are equally divided by the polarization beam splitter element when the rotation of the polarization plane by the magnetic field is 0.

In this case, it can be expressed by formula 10.

$$f ( {θ}_{offset} , {α}_{mod} , {ω}_{mod} , {φ}_{mod} , t ) = \frac{π}{4} sgn ( sin ( {ω}_{mod} t + {φ}_{mod} ) ) + {θ}_{offset} \qquad ( formula 10 )$$

Here, sgn(sin(ω_{mod}τ+φ_{mod}) represents a sign function which oscillates at the angular frequency ω_{mod}. When the minute measuring magnetic field is measured, it is assumed to be β<<1, and formula 3 is deformed as formula 11.

$$\begin{matrix}V ( t ) = & {V}_{0} cos ( 2 {θ}_{p} + 2 {θ}_{offset} + 2 β sin ( {ω}_{s} t + {φ}_{s} ) + \\ & 2 \cdot \frac{π}{4} sgn ( sin ( {ω}_{mod} t + {φ}_{mod} ) ) ) \\ \approx & {V}_{sin , 0} + {V}_{cos , 1}\end{matrix} \qquad ( formula 11 )$$

Here, V_{sin,0} and V_{cos,1} are expressed as formula 12.

$$\begin{matrix}{V}_{sin , 0} = \frac{4 {V}_{0}}{π} {J}_{0} ( 2 β ) sin ( 2 {θ}_{p} + 2 {θ}_{offset} ) {\sum }_{k = 1}^{∞} \frac{sin ( ( 2 k - 1 ) ( {ω}_{mod} t + {φ}_{mod} ) )}{2 k - 1} \\ {V}_{cos , 1} = \frac{4 {V}_{0}}{π} {J}_{1} ( 2 β ) cos ( 2 {θ}_{p} + 2 {θ}_{offset} ) \times \\ {\sum }_{k = 1}^{∞} \frac{sin ( ( {ω}_{s} + ( 2 k - 1 ) {ω}_{mod} ) t + {φ}_{s} + ( 2 k - 1 ) {φ}_{mod} )}{2 k - 1} + \frac{sin ( ( ( 2 k - 1 ) {ω}_{mod} - {ω}_{s} ) t + ( 2 k - 11 ) {φ}_{mod} - {φ}_{s} )}{2 k - 1}\end{matrix} \qquad ( formula 12 )$$

V_{sin,0} represents the oscillation of the polarization plane by the modulation, and V_{cos,1} represents the response to the measured magnetic field.

When the offset of the modulation function θ_{offset} is controlled so as to be θₚ+η_{offset}=±45°, V_{sin,0} becomes 0, and V_{sin,1} is maximized.

This indicates that the light is divided by the polarization plane angle modulation system 104 and that a difference of a component other than a signal component is obtained by the difference between the outputs of the photodetectors 106 and 107. The component other than the signal component is canceled out. Therefore, V_{sin,1} is used as the response to the measured magnetic field, and V_{cos,0} is obtained as the control signal by the frequency separation unit 110. The offset of the modulation function θ_{offset} is controlled so that the offset component of the output V_{offset} becomes 0. Then, the balance can constantly be maintained with the response to the magnetic signal maximizing.

However, unlike the case of a sinusoidal wave modulation, since the control signal is periodically varied, it is necessary to perform control in which the amplitude is reduced and the control signal finally becomes 0.

Therefore, compared with the case of the sinusoidal wave, the frequency separation unit 110 and the polarization plane angle modulation system control unit 111 are a little more complicated.

Specifically, for example, a high-pass filter can be used as the frequency separation unit 110, and a lock-in amplifier and a polarization offset control circuit can be used as the polarization plane angle modulation system control unit 111.

A component of k=1, which is the same frequency as the modulation frequency, out of the response to the measured magnetic field V_{cos,1} is applied to demodulate, and the response to the measured magnetic field is obtained. Then, the largest signal response can be obtained. At this time, it is preferable to use third harmonic of the control signal as the control signal, because this allows the control signal to be easily separated since the frequency difference between the control signal and the response to the measured magnetic field becomes larger.

As an example of a noise reduction effect in this case, an effect of the probe light on the light intensity noise is considered. Now, a case is considered where the probe light has the light intensity noise, and the intensity of the pump light changes so that the polarization plane rotates at an angle corresponding to a constant number.

At this time, it is expressed as V₀→V (t) to give the time dependence in formula 9. When it is assumed that the Fourier transforms of V_{sin,0}, and V_{sin,1} are V_{sin,0} (ω) and V_{sin,1} (ω) and that the noise power spectral density is β<<1, it is expressed by the following formula 13.

$${Φ}_{cos , 0} ( ω ) ∼ \vert {V}_{cos , 0} ( ω ) {\vert}^{2} = \vert \frac{4}{π} {J}_{0} ( 2 β ) sin ( 2 {Δθ}_{p} ) {\sum }_{k = 1}^{∞} {V}_{0} ( ( 2 k - 1 ) {ω}_{mod} + ω ) \frac{sin ( ( 2 k - 1 ) ( {ω}_{mod} t + {φ}_{mod} ) )}{2 k - 1} {\vert}^{2} \qquad ( formula 13 )$$

Here, Δθₚ represents a change amount of a rotation angle of the polarization plane caused by the change of the pump light intensity. When it is assumed that the power spectral component of the noise which is characterized by the reciprocal of the frequency is Φ_{sys} (ω), the minimum βₘᵢₙ of β is expressed as follows.

$${β}_{min} \approx \frac{π}{2} \frac{\sqrt{{Φ}_{sin , 0} ( {ω}_{s} ) + {Φ}_{sys} ( {ω}_{mod} + {ω}_{s} )}}{{V}_{0} ( 0 )} \qquad ( formula 14 )$$

Here, V₀ (0) represents the average intensity of the probe light. When the control is operated so as to be Δθₚ→0, it becomes V_{cos,0} (ωₛ)→0. The minimum βₘᵢₙ of β is expressed as follows.

$${β}_{min} \approx \frac{π}{2} \frac{\sqrt{{Φ}_{sys} ( {ω}_{mod} + {ω}_{s} )}}{{V}_{0} ( 0 )} \\ {β}_{min} \approx \frac{π}{2} \frac{\sqrt{{Φ}_{sys} ( {ω}_{mod} + {ω}_{s} )}}{{V}_{0} ( 0 )} \qquad ( formula 15 )$$

This indicates that the light intensity noise caused by the probe light is reduced by adjusting the offset of the polarization plane to be balanced in the difference detection.

$${β}_{min} \approx \frac{π}{2} \frac{\sqrt{{Φ}_{sys} ( {ω}_{mod} + {ω}_{s} )}}{{V}_{0} ( 0 )}$$

### EMBODIMENTS

Embodiments of the present invention are described hereinafter.

### First Embodiment

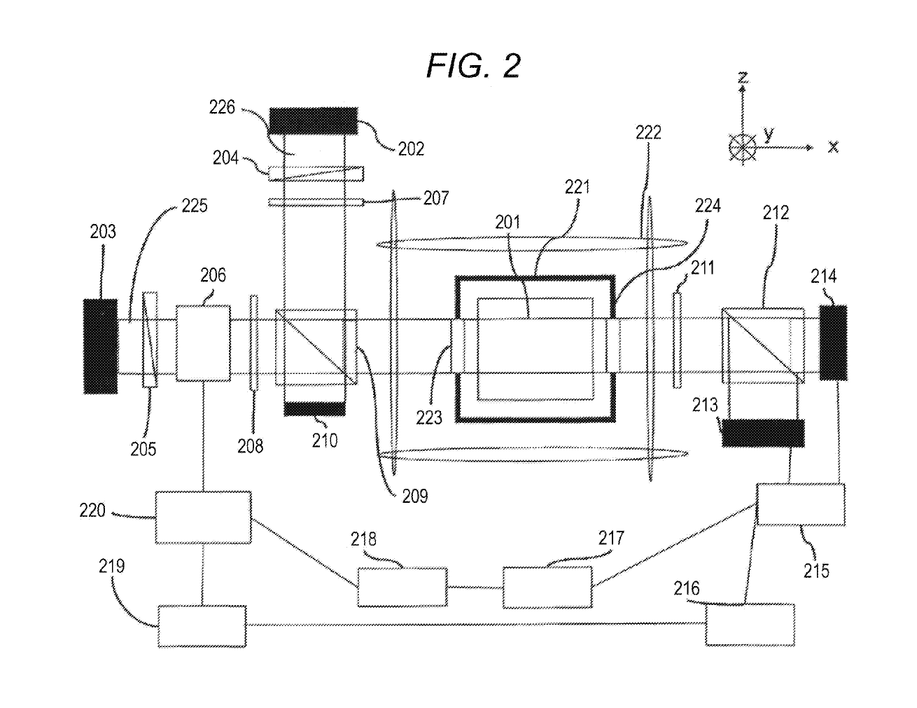

An exemplary configuration of an optically pumped magnetometer according to a first embodiment of the present invention is described with reference to FIG. 2.

As shown in FIG. 2, the optically pumped magnetometer of the present embodiment includes a cell 201 containing potassium (K), a pump light source 202, a probe light source 203, linear polarizers 204 and 205, an electrooptical phase modulation element 206, and ¼ wavelength plates 207 and 208.

Also, the optically pumped magnetometer includes a non-polarizing beam splitter 209, an optical terminator 210, a ½ wavelength plate 211, a polarization beam splitter element 212, photodetectors 213 and 214, a difference circuit 215, a lock-in amplifier 216, and a low-pass filter 217.

The optically pumped magnetometer further includes a polarization offset control circuit 218, an arbitrary waveform generator 219, a phase modulator power source 220, an isothermal heat-insulation bath 221, a three-axis Helmholtz coil 222, and optical windows 223 and 224.

The cell 201 is made of a material such as glass, which is transparent to probe light and pump light. In the hermetically sealed cell 201, potassium (K) is introduced as an alkali metal atom group.

Also, helium (He) and nitrogen (N₂) are introduced into and sealed in the cell 201 as buffer gas and quenching gas. Since the buffer gas suppresses diffusion of polarized alkali metal atoms, it is effective for suppressing a spin relaxation due to collisions against cell walls and for increasing a polarization rate. Also, N₂ gas is the quenching gas for absorbing energy from K which is in an excited state and for suppressing fluorescence. It is effective for increasing an optical pumping efficiency. Among the alkali metal atoms, K atoms have the smallest scattering cross section in a spin polarization destruction caused by collisions against K atoms and He atoms.

Therefore, it is preferable to use potassium as an alkali metal to configure a magnetic sensor which has a long relaxation time and a strong signal intensity.

Around the cell 201, the isothermal heat-insulation bath 221 is placed.

At the time of measurement, the cell 201 is heated to about 200° C. at a maximum in order to improve an alkali metal gas density in the cell 201. A heating method is to introduce inactive gas, which is heated by the isothermal heat-insulation bath 221, into the cell 201 from outside and to heat the cell 201.

The isothermal heat-insulation bath 221 has a role to prevent the heat from escaping to the outside. In the isothermal heat-insulation bath 221, the optical windows 223 and 224 are placed on an optical path of the probe light 225 so as to secure the optical path.

Also, around the isothermal heat-insulation bath 221, the three-axis Helmholtz coil 222 is placed in a magnetic shield which is not shown.

The magnetic shield reduces a magnetic field which enters from an external environment. The three-axis Helmholtz coil 222 is used to operate a magnetic field environment around the cell 201 so as to generate a resonance by matching a measuring frequency with the Larmor frequency.

A bias magnetic field is applied in a direction perpendicular to the probe light 225 (direction y or z in FIG. 2), and a magnetic field in the direction to which the bias magnetic field is applied is measured.

Also, the three-axis Helmholtz coil 222 is used to make an environment, in which a residual magnetic field is canceled out and the magnetic field is not applied in other directions (in FIG. 2, shown as direction x and one of directions y and z to which the bias magnetic field is not applied). Also, a shim coil may be added to correct unevenness of the magnetic field.

The pump light source 202 emits pump light 226, and a wavelength of the pump light 226 is tuned to a D1 transition resonance of the K atoms.

Polarized light of the pump light 226 is transformed into circularly polarized light by the ¼ wavelength plate 207 after being formed into linearly polarized light by the linear polarizer 204.

At this time, the polarized light may be transformed into either clockwise circularly polarized light or counterclockwise circularly polarized light.

The probe light source 203 emits the probe light 225, and a wavelength of the probe light 225 is detuned about several GHz from the D1 transition resonance of the potassium atoms so that the signal response is maximized.

A value of detuning which maximizes the signal response depends on a buffer gas pressure and a temperature of the cell 201. The polarized light of the probe light 225 is formed into the linearly polarized light by the linear polarizer 205.

The pump light 226 is overlapped with the optical path of the probe light 225 by the non-polarizing beam splitter 209. It is not necessary for the optical path to be perfectly identical to the probe light 225. As long as an area through which the probe light 225 passes can be sufficiently polarized in the cell 201, the optical path may intersect with the probe light 225 at a small angle.

The non-polarizing beam splitter 209 has two exits. In the optical path which does not lead to the cell 201, the optical terminator 210 is arranged and performs a termination process.

When a voltage is applied to the electrooptical phase modulation element 206 by the phase modulator power source 220, a birefringence of a crystal changes in proportion to the voltage.

The change of the birefringence causes a change of a phase difference to the light which passes through the crystal, and the polarization state of the light changes. The phase difference of the incident probe light 225, which is in the polarization state of the linearly polarized light, changes according to the voltage applied to the electrooptical phase modulation element 206, and the probe light 225 goes into an elliptical polarization state.

The electrooptical phase modulation element 206 and the ¼ wavelength plate 208, through which the probe light 225 passes thereafter, are each rotated at an appropriate angle about the crystal axial direction so that the change of the phase difference is converted to a rotation of a linear polarization plane.

As a result, when a sinusoidal voltage is applied to the electrooptical phase modulation element 206, the angle of the polarization plane of the probe light 225 is sinusoidally varied.

Although it is preferable that an amplitude of the oscillation be about α_{mod}=87.5°, in which J₂ (2α_{mod}) is maximized, the amplitude of the oscillation may be smaller than α_{mod}=87.5°.

It is preferable that a frequency of the sinusoidal wave be equal to or higher than 1 kHz. When a voltage is applied to an offset control part of the phase modulator power source 220, an offset is added to the angle of the polarization plane of the probe light in proportion to the voltage.

The amplitude of the oscillation is proportionate to the applied voltage to the electrooptical phase modulation element 206. Another method in which the polarization plane is modulated by the magnetic field by using the Faraday effect can be considered.

At this time, it is preferable that a modulator be kept away or shielded from a varying magnetic field in order to reduce an influence on magnetometry of the varying magnetic field used to modulate the polarization plane.

A polarization measuring system includes the ½ wavelength plate 211, the polarization beam splitter element 212, the photodetectors 213 and 214, the difference circuit 215, and the lock-in amplifier 216.

According to a polarization angle θ of incident light, the polarization beam splitter element 212 divides the light into two light beams having an intensity ratio of cos²θ:sin²θ.

Here, it is assumed that a polarization state in which all the incident light beams pass through is θ=0° as a reference. The light intensities of the two divided light beams are measured by the photodetectors 213 and 214, respectively, and a difference between the outputs of the photodetectors 213 and 214 is read by the difference circuit 215.

When the light, which has a polarization angle of θ=45° or θ=−45°, is incident on the polarization beam splitter element 212, the light is divided into light beams having equal intensities. The output of the difference circuit 215 becomes 0. First, a case where the modulation is not applied is considered.

Further, when a spin polarization by the pump light 226 does not exist, the polarization plane of the probe light 225 stays at θ=45°. The probe light 225 enters the polarization beam splitter element 212 and is divided into light beams having equal intensities, and the output of the difference circuit 215 becomes 0.

Next, a case where the spin polarization by the pump light 226 exists is considered. At this time, through the spin polarization by the pump light 226, the polarization plane of the probe light 225, which has passed through the cell 201, receives a rotation with a magnitude proportional to a magnitude of the spin polarization, and the probe light 225 enters the polarization beam splitter element 212. At this time, the pump light 226 has a different angle from θ=45°.

Therefore, the output of the difference circuit does not become 0. When the magnitude of the spin polarization is fluctuated by the fluctuation of a pump light intensity and a bias magnetic field intensity, the output of the difference circuit also fluctuates. Next, a case where the modulation is applied is considered. At this time, the polarization plane of the probe light 225 sinusoidally oscillates. The probe light 225 is divided by the polarization beam splitter element 212, and the intensities of the divided light beams are respectively measured by the photodetectors 213 and 214. A difference between the outputs of the photodetectors 213 and 214 is read by the difference circuit 215, and lock-in detection is performed by the lock-in amplifier 216. A modulation signal, which is applied to the electrooptical phase modulation element 206 in the arbitrary waveform generator 219, is used to demodulate.

### Second Embodiment

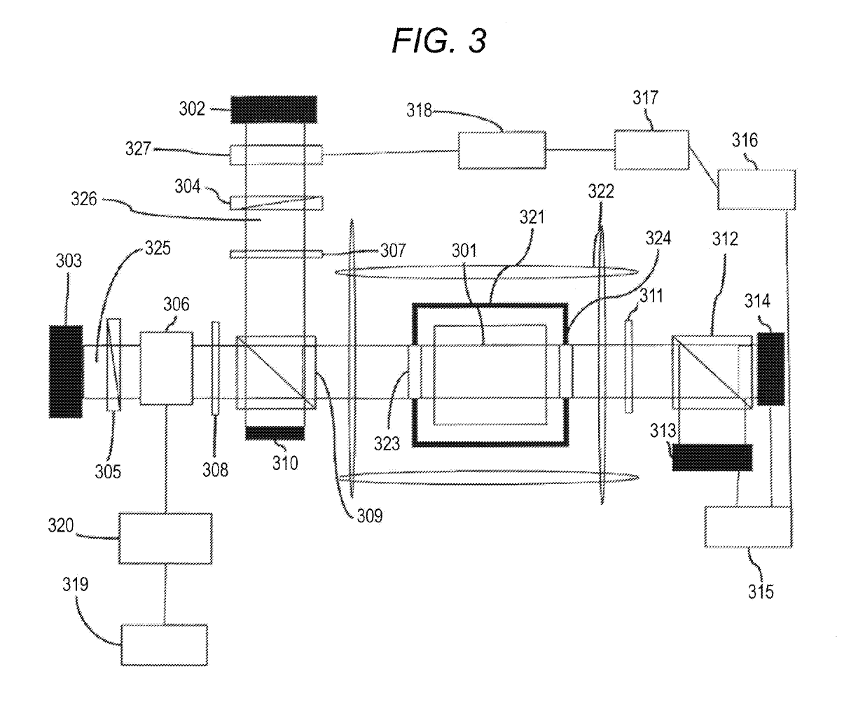

An exemplary configuration of an optically pumped magnetometer according to a second embodiment of the present invention is described with reference to FIG. 3.

As shown in FIG. 3, the optically pumped magnetometer of the present embodiment includes a cell 301 containing potassium (K), a pump light source 302, a probe light source 303, linear polarizers 304 and 305, an electrooptical phase modulation element 306, and ¼ wavelength plates 307 and 308.

Also, the optically pumped magnetometer includes a non-polarizing beam splitter 309, an optical terminator 310, a ½ wavelength plate 311, a polarization beam splitter element 312, photodetectors 313 and 314, a difference circuit 315, a lock-in amplifier 316, and a low-pass filter 317.

The optically pumped magnetometer further includes a polarization offset control circuit 318, an arbitrary waveform generator 319, a phase modulator power source 320, an isothermal heat-insulation bath 321, a three-axis Helmholtz coil 322, optical windows 323 and 324, and an intensity modulator 327.

The cell, the isothermal heat-insulation bath, the three-axis Helmholtz coil, the probe light source, a beam coupling unit, a polarization modulation system, and a polarization measuring system are the same as those in the above first embodiment.

The pump light source 302 emits pump light 326, and a wavelength of the pump light 326 is tuned to a D1 transition resonance of K atoms.

An intensity of the pump light is changed according to an output of the control circuit 318 by the intensity modulator 327. As the intensity modulator 327, a combination of an electrooptical phase modulation element and a polarization plate, or an acousto-optical element can be used.

By using a frequency modulator instead of the intensity modulator, a frequency of the pump light 326 may be controlled by the output from the control circuit 318.

As the frequency modulator, the acousto-optical element or the like can be used. Also, the intensity or the frequency of the pump light 326 can be controlled by controlling, for example, a value of an oscillating current of the pump light source by the output of the control circuit 318.

Polarized light of the pump light 326 is transformed into circularly polarized light by the ¼ wavelength plate 307 after being formed into linearly polarized light by the linear polarizer 304. At this time, the polarized light may be transformed into either clockwise circularly polarized light or counterclockwise circularly polarized light.

### Third Embodiment

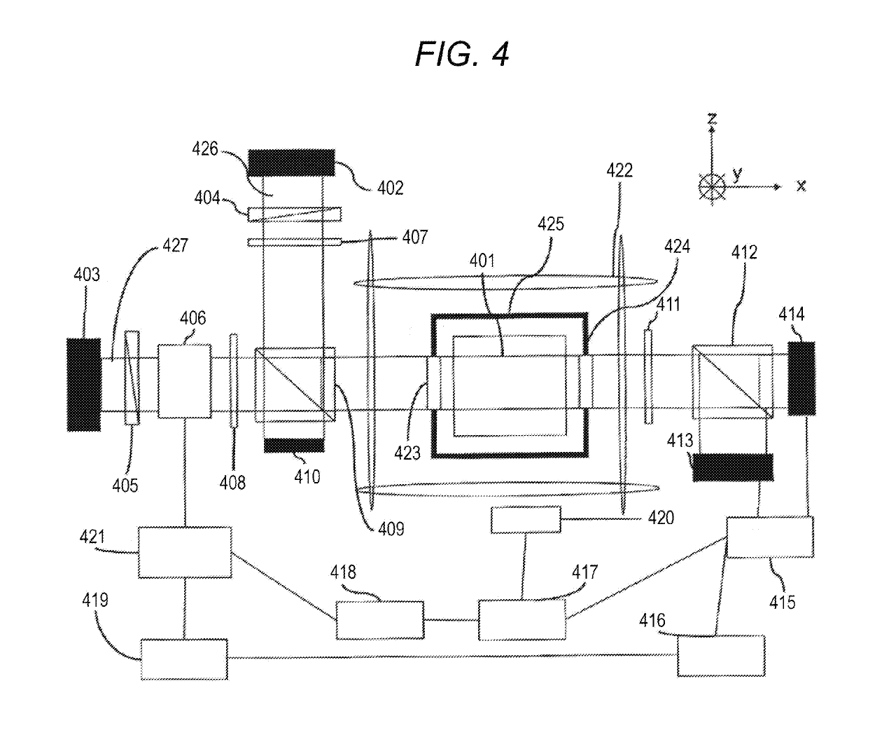

An exemplary configuration of an optically pumped magnetometer according to a third embodiment of the present invention is described with reference to FIG. 4.

As shown in FIG. 4, the optically pumped magnetometer of the present embodiment includes a cell 401 containing potassium (K), a pump light source 402, a probe light source 403, linear polarizers 404 and 405, an electrooptical phase modulation element 406, ¼ wavelength plates 407 and 408, a non-polarizing beam splitter 409, an optical terminator 410, and a ½ wavelength plate 411. Also, the optically pumped magnetometer includes a polarization beam splitter element 412, photodetectors 413 and 414, a difference circuit 415, lock-in amplifiers 416 and 417, a polarization offset control circuit 418, arbitrary waveform generators 419 and 420, a phase modulator power source 421, a three-axis Helmholtz coil 422, optical windows 423 and 424, and an isothermal heat-insulation bath 425.

The cell, the isothermal heat-insulation bath, the three-axis Helmholtz coil, the pump light source, the probe light source, a beam coupling unit, and a polarization measuring system are the same as those in the above first embodiment.

When a square wave voltage is applied to the electrooptical phase modulation element 406, an angle of a polarization plane of probe light 427 is sinusoidally varied.

It is preferable to set an amplitude of the oscillation to be α_{mod}=90°, because in this case an output of the difference circuit become 0 when an offset of the angle of the polarization plane is 0.

Also, it is preferable that a frequency of the square wave be equal to or higher than 1 kHz. When a voltage is applied to an offset control part of the phase modulator power source 421, an offset is added to the angle of the polarization plane of the probe light 427 in proportion to the voltage.

By detecting the output of the difference circuit 415 by the lock-in amplifier 416 at the same frequency as the frequency of the square wave input into the electrooptical phase modulation element 406, a measured magnetic signal can be obtained.

Also, information on the offset of the angle of the polarization plane of the probe light 427 can be obtained when the lock-in amplifier 417 detects the output of the difference circuit 415 at an odd multiple frequency of the frequency of the square wave. The frequency may be any odd multiple of the frequency. However, it is preferable that the frequency be third harmonic in order to obtain as big a control signal as possible while the frequency is separated from a measured magnetic field signal.

A voltage is applied to the offset control part of the phase modulator power source 421 by the control circuit 418 so that an output from the lock-in amplifier 417 detected by the third harmonic becomes 0.

According to an embodiment of the present invention, an optically pumped magnetometer and an optical pumping magnetic force measuring method capable of suppressing an influence by a fluctuation of a spin polarization and reducing noise can be realized.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-149135, filed on Jul. 18, 2013, which is hereby incorporated by reference herein in its entirety.

What is claimed is:

1. An optically pumped magnetometer having a single optical axis using atomic electron spin or nuclear spin, the optically pumped magnetometer comprising:
a detection unit configured to detect an angle of a polarization plane of a probe light having components of linear polarization; and
a modulation unit configured to apply a modulation to the angle of the polarization plane of the probe light having the components of linear polarization, wherein
the modulation unit is configured to control an offset in applying the modulation to the angle of the polarization plane of the probe light having the components of linear polarization according to the angle of the polarization plane of the probe light detected by the detection unit.

2. The optically pumped magnetometer according to claim 1, wherein
the detection unit includes a polarization beam splitter element and a difference circuit configured to detect a difference between light intensities of the components which have been separated by the polarization beam splitter element, and
the modulation unit controls the offset to maintain a balance of the difference between the light intensities which has been detected by the difference circuit.

3. The optically pumped magnetometer according to claim 2, comprising:
a unit configured to control an intensity or a frequency of pump light, as a unit to control the offset.

4. The optically pumped magnetometer according to claim 1, wherein
the modulation unit is configured to apply a sinusoidal modulation to the angle of the polarization plane of the probe light.

5. The optically pumped magnetometer according to claim 1, wherein
the modulation unit is configured to apply a square wave modulation to the angle of the polarization plane of the probe light.

6. The optically pumped magnetometer according to claim 2, comprising:
a unit configured to detect an output of the difference circuit at the same frequency as a square wave frequency input into the modulation unit and to obtain a measured magnetic signal.

7. The optically pumped magnetometer according to claim 2, comprising:
a unit configured to detect an output of the difference circuit at an odd multiple frequency of a square wave frequency input into the modulation unit.

8. A single-optical-axial optical pumping magnetic force measuring method for detecting an angle of a polarization plane of probe light having components of linear polarization by using atomic electron spin or nuclear spin, the method comprising:
controlling an offset in applying a modulation to the angle of the polarization plane of the probe light having the components of linear polarization according to the detected angle of the polarization plane of the probe light.

9. The optical pumping magnetic force measuring method according to claim 8, comprising:
detecting a difference between light intensities of the components which have been separated by a polarization beam splitter element when the angle of the polarization plane of the probe light having the components of linear polarization is detected; and
controlling the offset to maintain a balance of the difference between the detected light intensities.

10. The optical pumping magnetic force measuring method according to claim 9, comprising:
controlling an intensity or a frequency of pump light when the offset is controlled.

11. The optical pumping magnetic force measuring method according to claim 9, comprising:
applying a sinusoidal modulation to the angle of the polarization plane of the probe light having the components of linear polarization when the offset is controlled.

12. The optical pumping magnetic force measuring method according to claim 9, comprising:
applying a square wave modulation to the angle of the polarization plane of the probe light having the components of linear polarization when the offset is controlled.

13. The optical pumping magnetic force measuring method according to claim 9, comprising:
obtaining a measured magnetic signal by detecting an output of the difference at the same frequency as a square wave frequency input at the time of the modulation.

14. The optical pumping magnetic force measuring method according to claim 9, comprising:
obtaining information on the offset of the angle of the polarization plane of the probe light by detecting an output of the difference at an odd multiple frequency of a square wave frequency input at the time of the modulation.
